(19) United States
(12) Patent Application Publication
(10) Pub. No.: US 2025/0253192 A1
(43) Pub. Date: Aug. 7, 2025

(54) BARRIER AND LINER TREATMENT USING DUAL RADIO FREQUENCY CAPACITIVE COUPLE PLASMA FOR METAL INTERCONNECTS

(71) Applicant: Applied Materials, Inc., Santa Clara, CA (US)

(72) Inventors: Shinjae HWANG, Santa Clara, CA (US); Kevin KASHEFI, Dublin, CA (US)

(21) Appl. No.: 18/433,936

(22) Filed: Feb. 6, 2024

(51) Int. Cl. H01L 21/768; H01J 37/32

(52) U.S. Cl. CPC H01L 21/76843; H01J 37/32091; H01J 37/32165; H01L 21/76876; H01J 2237/332

(57) ABSTRACT

A processing method includes depositing a barrier layer on a field region and sidewalls of a via of an interconnect structure, wherein depositing the barrier layer comprises establishing a single RF frequency capacitively coupled plasma (CCP) using a first radio frequency (RF) generator by delivering a first RF signal from the first radio frequency (RF) generator at a first RF frequency to a first electrode, and treating the barrier layer by establishing a dual RF frequency CCP, wherein the dual RF frequency CCP is formed using the first RF generator and a second RF generator coupled to the first electrode, the dual RF frequency CCP is formed by simultaneously delivering a second RF signal at the first RF frequency to the first electrode and a third RF signal at a second RF frequency to the first electrode, and the first RF frequency is greater than the second RF frequency.

### BACKGROUND

### Field

Embodiments of the present disclosure generally relate to a system and method used in semiconductor device manufacturing. More specifically, embodiments of the present disclosure relate to a plasma processing system and method used to process a substrate using a plasma.

### Description of the Related Art

Reliably producing high aspect ratio features is one of the key technology challenges for the next generation of semiconductor devices. One method of forming high aspect ratio features uses a plasma-assisted etching process to bombard a material formed on a surface of a substrate through openings formed in a patterned mask layer formed on the substrate surface.

In fabrication of an integrated circuit, middle-end-of-line (MEOL) and back-end-of-line (BEOL) stages may include forming gate regions of transistors and local interconnect layers. Typically processing operations during MEOL and BEOL stages include generating a plasma using a single radio frequency (RF) signal. For example, depositing and treating barrier layers or liner layers formed on sidewalls of vias and/or trenches formed in interconnect structures, and removing a passivation layer formed within the vias and/or trenches are each performed using a plasma generated from a single RF source. Stated differently, conventional plasma processing chambers used during MEOL and BEOL stages typically generate a plasma using single RF source, and therefore, are limited to generating a plasma using a single RF frequency (i.e., a single RF frequency plasma) for deposition, treatment, and removal. However, the single RF frequency plasma increases in energy and flux at the same time. During deposition and removal, a plasma that has highly energetic species and/or a high plasma density can cause damage to the dielectric layer(s) (i.e., the low-k layers) of the interconnect structure. On the other hand, during treatment a plasma that doesn't have enough energetic species and/or the plasma density is low may not allow for sufficient treatment of the device layers.

Therefore, there is a need in the art for a plasma processing system and method that can deposit, treat, and/or remove layers during MEOL and BEOL stages without damaging the dielectric layers of the interconnect structure while being able to sufficiently treat layers.

### SUMMARY

In an embodiment, a processing method includes depositing a barrier layer on a field region and sidewalls of a via of an interconnect structure, wherein depositing the barrier layer comprises establishing a single RF frequency capacitively coupled plasma (CCP) using a first radio frequency (RF) generator coupled to a first electrode of a plasma processing chamber, and the single RF frequency CCP is formed by delivering a first RF signal from the first radio frequency (RF) generator at a first RF frequency to the first electrode, and treating the barrier layer by establishing a dual RF frequency CCP in the plasma processing chamber, wherein the established dual RF frequency CCP is formed by use of the first RF generator and a second RF generator coupled to the first electrode of the plasma processing chamber, the dual RF frequency CCP is formed by simultaneously delivering a second RF signal at the first RF frequency to the first electrode and a third RF signal at a second RF frequency to the first electrode, and the first RF frequency is greater than the second RF frequency.

In another embodiment, a plasma processing system includes a first radio frequency (RF) generator coupled an upper electrode of a processing chamber of the plasma processing system, the first RF generator configured to generate a first RF signal having a first frequency, a second RF generator coupled the upper electrode of the processing chamber of the plasma processing system, the second RF generator configured to generate a second RF signal having a second frequency, the second frequency and the first frequency being different, a controller, and a memory for storing instructions, which, when executed by the controller, causes the controller to perform a processing method, the method including establishing, by use of the first RF generator, a single RF frequency capacitively coupled plasma (CCP), during performing a first processing operation on an interconnect structure, and establishing, by use of the first RF generator and the second RF generator, a dual RF frequency CCP during performing a second processing operation on the interconnect structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional views an example processing system, according to one or more embodiments.

FIG. 2 is a process flow diagram of a method for processing a substrate using plasmas generated with different radio frequencies according to one or more embodiments.

FIGS. 3A-3E are cross-sectional views of a portion of a substrate during a method for processing a substrate using plasmas generated with different radio frequencies according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

During conventional deposition, treatment, and removal processes used during MEOL and BEOL stages of device manufacturing, a plasma is typically generated by use of a single radio frequency (RF) signal provided from a single RF source (i.e., a single RF frequency plasma). For example, during deposition and treatment of barrier layers or liner layers formed on sidewalls of vias and/or trenches formed in interconnect structures, and removal of a passivation layer formed within the vias and/or trenches, plasmas are typically generated by the delivery of an RF signal from a single RF source to an electrode within a processing chamber. Therefore, the plasmas used for deposition, treatment, and removal processes are restricted to being generated using a same fundamental RF frequency. If the generated plasma is too strong, such as when the plasma contains highly energetic species and/or a high plasma density, then during deposition and removal processes, dielectric layers of the interconnect structures can be damaged. If the plasma is too weak, such as when the plasma that doesn't have enough energetic species and/or the plasma density is low, then the layers are not fully treated during the plasma treatment processes.

Embodiments of the present disclosure generally relate to a system and method for depositing, treating, and removing layers in an interconnect structure. In particular, embodiments herein relate to using a single RF frequency plasma during a first portion of a plasma process and a dual RF frequency plasma during a second portion of the plasma process. In one example, a plasma process will include the use of a single RF frequency plasma for depositing and removing layers of the interconnect structure, and using a dual RF frequency plasma for treating layers of the interconnect structure to prevent damage to the low-k (i.e., dielectric layers) during deposition and removal and ensure that a strong enough plasma is generated for proper treatment.

### Substrate Processing System Example

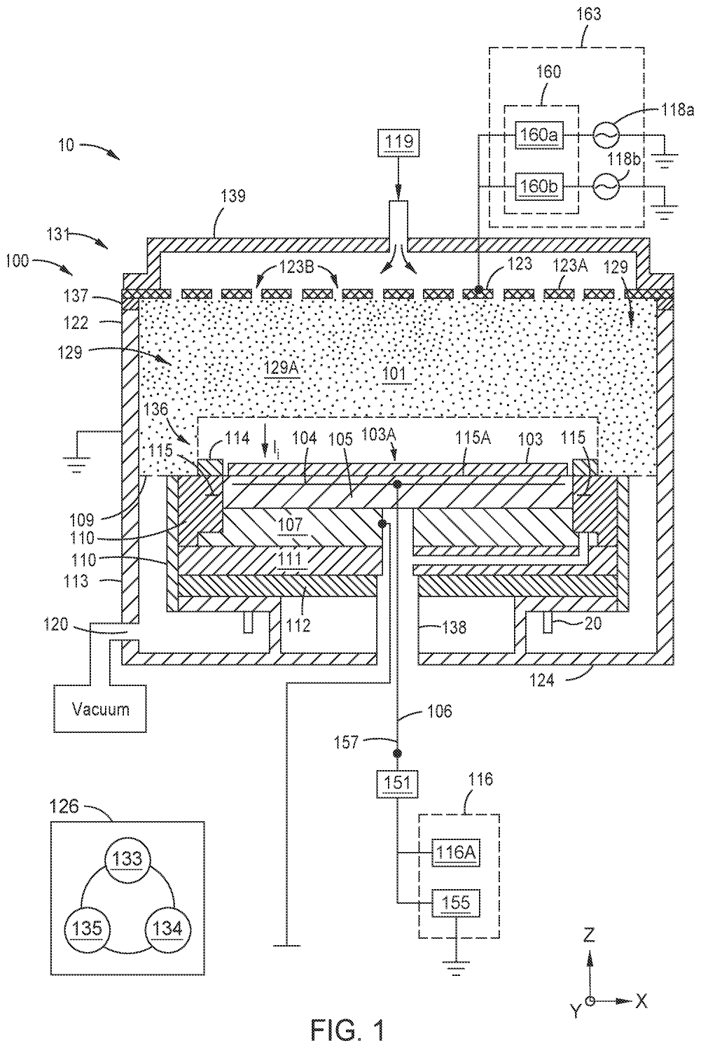

FIG. 1 is a schematic cross-sectional views an example processing system 10 configured to perform one or more of the plasma processing methods set forth herein. In some embodiments, the processing system 10 illustrated in FIG. 1 are configured for plasma-assisted etching processes, such as a reactive ion etch (RIE) plasma processing. However, it should be noted that the embodiments described herein may also be used with processing systems configured for use in other plasma-assisted processes, such as plasma-enhanced deposition processes, for example, plasma-enhanced chemical vapor deposition (PECVD) processes, to atomic layer deposition (ALD), plasma-enhanced physical vapor deposition (PEPVD) processes, plasma-enhanced atomic layer deposition (PEALD) processes, plasma treatment processing or plasma-based ion implant processing, for example, plasma doping (PLAD) processing.

As shown in FIG. 1 the processing system 10 is configured to form a capacitively coupled plasma (CCP), where the processing system 10 includes an upper electrode (e.g., chamber lid 123) disposed in a processing volume 129 facing a lower electrode (e.g., the substrate support assembly 136) also disposed in the processing volume 129. A plasma generator assembly 163 is electrically coupled to one of the upper electrode or lower electrode to deliver an RF signal that is used to ignite and maintain a plasma 101 in a processing region 129A disposed over the substrate 103. The plasma generator assembly 163 will generally include a first RF generator 118a, a second RF generator 118b, and an RF matching network 160. The RF matching network 160 will generally include a first RF match 160a coupled to the first RF generator 118a and a second RF match 160b coupled to the second RF generator 118b. In one example, the output of the RF matching network 160 (i.e., the outputs of the first RF match 160a and the second RF match 160b) are coupled to the upper electrode, such as the showerhead plate 123A. In some embodiments, the first RF generator 118a is configured to deliver an RF signal having a frequency that is greater than 400 kHz, such as an RF frequency ranging between 20 MHz and 120 MHz, such as about 60 MHz. The second RF generator 118b is configured to deliver an RF signal have a frequency that is greater than 400 kHz, such as an RF frequency ranging between 1 MHz and 20 MHz, such as about 13.56 MHz. Stated differently, the first RF generator 118a generates an RF signal with a higher frequency than the second RF generator 118b.

The processing system 10 further includes a processing chamber 100, a substrate support assembly 136, and a system controller 126. The processing chamber 100 typically includes a chamber body 113 that includes the chamber lid 123, one or more sidewalls 122, and a chamber base 124, which collectively define the processing volume 129. A substrate 103 is loaded into, and removed from, the processing volume 129 through an opening (not shown) in one of the one or more sidewalls 122, which is sealed with a slit valve (not shown) during plasma processing of the substrate 103. The one or more sidewalls 122 and chamber base 124 generally include materials that are sized and shaped to form the structural support for the elements of the processing chamber 100 and are configured to withstand the pressures and added energy applied to them while a plasma 101 is generated within a vacuum environment maintained in the processing volume 129 of the processing chamber 100 during processing. In one example, the one or more sidewalls 122 and chamber base 124 are formed from a metal, such as aluminum, an aluminum alloy, or a stainless steel alloy. In some embodiments, there is a dielectric coating on the sidewalls 122. The dielectric coating can be anodized aluminum, aluminum oxide, yttrium oxide, mixtures thereof. The thickness of the dielectric coating can vary from 1 nm to 10 cm.

The system controller 126, also referred to herein as a processing chamber controller, includes a central processing unit (CPU) 133, a memory 134, and support circuits 135. The system controller 126 is used to control the process sequence used to process the substrate 103, including the substrate biasing methods described herein. The CPU 133 is a general-purpose computer processor configured for use in an industrial setting for controlling the processing chamber and sub-processors related thereto. The memory 134 described herein, which is generally non-volatile memory, may include random access memory, read-only memory, floppy or hard disk drive, or other suitable forms of digital storage, local or remote. The support circuits 135 are conventionally coupled to the CPU 133 and comprise cache, clock circuits, input/output subsystems, power supplies, and the like, and combinations thereof. Software instructions (program) and data can be coded and stored within the memory 134 for instructing a processor within the CPU 133. A software program (or computer instructions) readable by CPU 133 in the system controller 126 determines which tasks are performable by the components in the processing system 10. Typically, the program, which is readable by CPU 133 in the system controller 126, includes code, which, when executed by the processor (CPU 133), performs tasks relating to the plasma processing schemes described herein. The program may include instructions that are used to control the various hardware and electrical components within the processing system 10 to perform the various process tasks and various process sequences used to implement the methods described herein. In one embodiment, the program includes instructions that are used to perform one or more of the operations described below.

The substrate support assembly 136, which generally includes the substrate support 105 (e.g., electrostatic-chuck (ESC) substrate support) and support base 107, is disposed on a support shaft 138 that is grounded and extends through the chamber base 124. In some embodiments, the substrate support assembly 136 can additionally include an insulator plate 111 and a ground plate 112. The support base 107 is electrically isolated from the chamber base 124 by the insulator plate 111, and the ground plate 112 is interposed between the insulator plate 111 and the chamber base 124. The substrate support 105 is thermally coupled to and disposed on the support base 107. In some embodiments, the support base 107 is configured to regulate the temperature of the substrate support 105, and the substrate 103 disposed on the substrate support 105, during substrate processing. In some embodiments, the support base 107 includes one or more cooling channels (not shown) disposed therein that are fluidly coupled to, and in fluid communication with, a coolant source (not shown), such as a refrigerant source or water source having a relatively high electrical resistance. In some embodiments, the substrate support 105 includes a heater (not shown), such as a resistive heating element embedded in the dielectric material thereof. Herein, the support base 107 is formed of a corrosion-resistant thermally conductive material, such as a corrosion-resistant metal, for example aluminum, an aluminum alloy, or a stainless steel and is coupled to the substrate support with an adhesive or by mechanical means.

In some alternate embodiments of FIG. 1, the plasma generator assembly 163 and its components (e.g., the first RF generator 118a, second RF generator 118b, and RF matching network 160) are coupled to the support base 107 or bias electrode 104 instead of the showerhead plate 123A.

In some embodiments, the process chamber 100 further includes the quartz pipe 110, or collar, that at least partially circumscribes portions of the substrate support assembly 136 to prevent the substrate support 105 and/or the support base 107 from contact with corrosive processing gases or plasma, cleaning gases or plasma, or byproducts thereof. Typically, the quartz pipe 110, the insulator plate 111, and the ground plate 112 are circumscribed by a cathode liner 108. In some embodiments, a plasma screen 109 is positioned between the cathode liner 108 and the sidewalls 122 to prevent plasma from forming in a volume underneath the plasma screen 109 between the cathode liner 108 and the one or more sidewalls 122.

The substrate support 105 is typically formed of a dielectric material, such as a bulk sintered ceramic material, such as a corrosion-resistant metal oxide or metal nitride material, for example, aluminum oxide (Al₂O₃), aluminum nitride (AlN), titanium oxide (TiO), titanium nitride (TiN), tantalum nitride (TaN), yttrium oxide (Y₂O₃), mixtures thereof, or combinations thereof. In embodiments herein, the substrate support 105 further includes the bias electrode 104 embedded in the dielectric material thereof. In one configuration, the bias electrode 104 is a chucking pole used to secure (i.e., chuck) the substrate 103 to the substrate support surface 105A of the substrate support 105 and to bias the substrate 103 with respect to the plasma 101 using one or more of the pulsed-voltage biasing sources (not shown), which comprise a voltage waveform generator (e.g., variable DC source). Typically, the bias electrode 104 is formed of one or more electrically conductive parts, such as one or more metal meshes, foils, plates, or combinations thereof.

In some embodiments, the chamber lid 123 and substrate support assembly 136 are configured in a parallel plate like configuration, such that the showerhead plate 123A of the chamber lid 123 is substantially parallel to the substrate support surface 105A of the of the substrate support assembly 136. The showerhead plate 123A can include a conductive metal plate that includes a plurality of holes 123B that are configured to distribute a process gas delivered from the processing gas source 119. In some alternate embodiments, the chamber lid 123 has a low angled concave conical shape or slightly curved concave shape relative to the flat substrate support assembly 136, which is centered about the center of chamber lid 123.

The overall control of the delivery of the first RF generator 118a and the second RF generator 118b are controlled by use of signals provided from the system controller 126. For example, the plasma generator assembly 163 is generally configured to deliver a desired amount of a continuous wave (CW) or pulsed RF power at different waveform frequencies to the chamber lid 123 for different plasma processing steps based on the control signals provided from the system controller 126. This will be described in more detail below.

Referring to FIG. 1 the substrate support assembly 136 an edge ring 114 positioned within a region of the substrate support 105. For example, the edge ring 114 is disposed on and adjacent to the substrate support 105. In this configuration, the edge ring 114 is formed from a semiconductor or dielectric material (e.g., AlN, etc.).

As noted above, in some embodiments, the bias electrode 104 is electrically coupled to a clamping network 116, which provides a chucking voltage thereto, such as static DC voltage between about −5000 V and about 10,000 V, using an electrical conductor, such as the coaxial power delivery line 106 (e.g., a coaxial cable). The application of a sufficient clamping voltage to the bias electrode 104 can facilitate the temperature control of the substrate 103 and the edge ring 114. The clamping network 116 includes bias compensation circuit elements 116A, and a DC power supply 155. In some embodiments, the clamping network is coupled to an RF filter assembly 151 that is configured to block the RF signal generated by the plasma generator assembly 163 and any associated harmonics, from making their way to the clamping network 116 or the DC power supply 155.

In some embodiments, the upper electrode assembly 131 includes the upper electrode (e.g., showerhead plate 123A of the chamber lid 123) and a lid plate 139, which are configured to form a showerhead assembly that is configured to evenly distribute one or more gases provided from the processing gas source 119 to the process region 129A through a plurality of holes 123B formed in the upper electrode. The processing volume 129 is fluidly coupled to one or more dedicated vacuum pumps through a vacuum outlet 120, which maintain the processing volume 129 at sub-atmospheric pressure conditions and evacuate processing and/or other gases, therefrom.

The upper electrode assembly 131 is also positioned on, and electrically isolated from, the grounded sidewalls 122 by a lid insulator 137. As shown in FIG. 1, one or more components of the substrate support assembly 136, such as the support base 107 are grounded. As shown in FIG. 1, an upper electrode, such as the showerhead plate 123A of the chamber lid 123, is electrically coupled to at the plasma generator assembly 163, which configured to ignite and maintain a plasma 101 in a processing region therebetween. In some embodiments, as noted above, the plasma generator assembly 163 is generally configured to deliver a desired amount of a continuous wave (CW) or pulsed RF power at different waveform frequencies to the chamber lid 123 for different plasma processing steps based on control signals provided from the system controller 126. Stated differently, the plasma generator assembly 163 is able to provide RF signals with at least two different frequencies by enabling one of or both of the RF generators during processing to effectively modulate the ion flux and ion energy provided by the plasma to reach the optimum regime during plasma processing.

### Substrate Processing Sequences

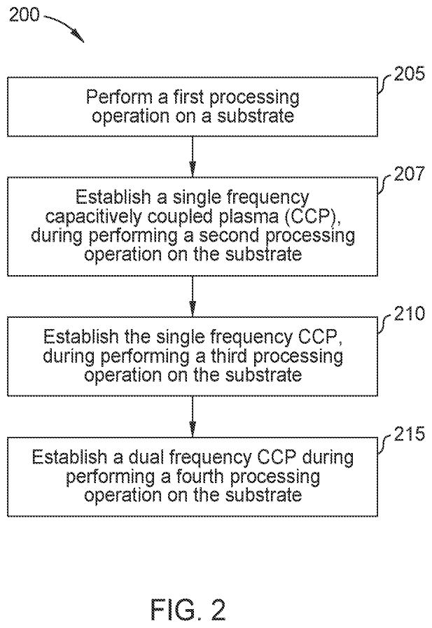

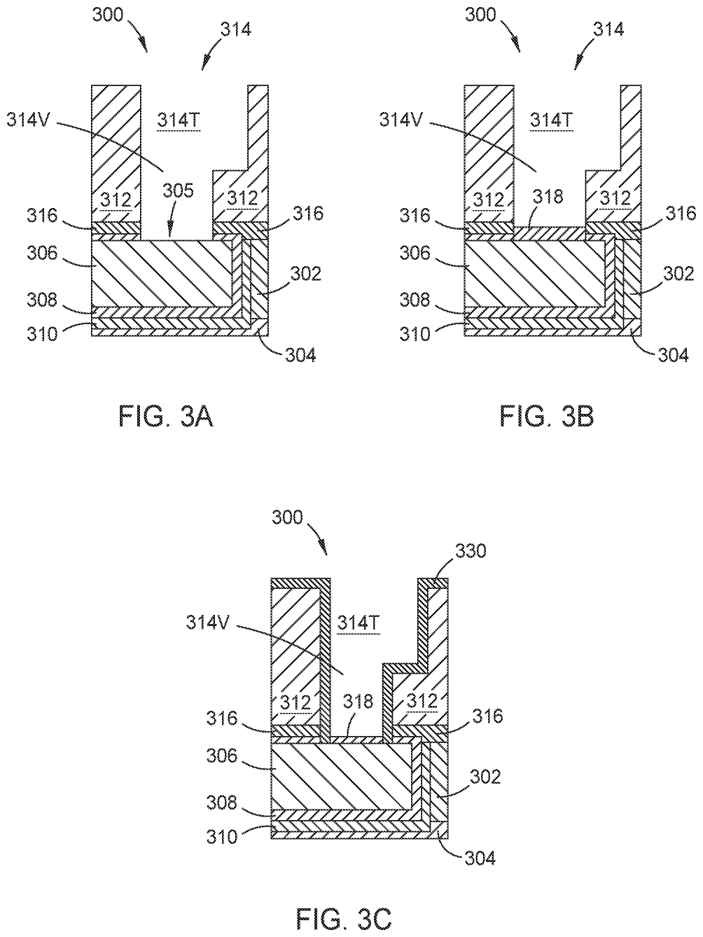

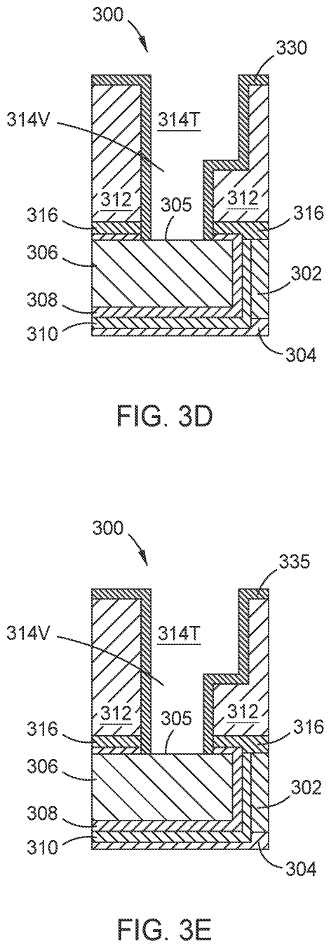

FIG. 2 is a process flow diagram of a method for processing a substrate using plasmas generated with different radio frequencies according to one or more embodiments. FIGS. 3A-3E are cross-sectional views of a portion of a substrate during a method for processing a substrate using plasmas generated with different radio frequencies according to one or more embodiments.

It should be understood that FIGS. 3A-3E illustrate only partial schematic views of the substrate, and the substrate may contain any number of device structures and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The method 200 begins at block 205 by performing a first processing operation on a substrate. In one example, as shown in FIG. 3A, the substrate includes an interconnect structure 300 that includes a first dielectric layer 302 formed on the substrate. The first dielectric layer 302 may be formed of a dielectric material, such as a low k dielectric, silicon dioxide (SiO₂), silicon nitride (Si₃N₄), silicon carbide (SiC), aluminum oxide (Al₂O₃), or aluminum nitride (AlN). In some embodiments, the low-k dielectric material can include one or more silicon oxide (SiOₓ), silicon nitride (SiN), and silicon carbonitride (SiCN), or silicon carbonoxyntride (SiOCN) material. A first etch stop layer 304 may be disposed between the first dielectric layer 302 and the substrate. The interconnect structure 300 further includes a conductive layer 306 embedded within the first dielectric layer 302 and separated from the first dielectric layer 302 by a liner layer 308 and a barrier layer 310. The conductive layer 306 may be formed of copper (Cu), cobalt (Co), molybdenum (Mo), tungsten (W), or ruthenium (Ru). The liner layer 308 may be formed of ruthenium (Ru), cobalt (Co), or ruthenium and cobalt (RuCo). The barrier layer 310 may be formed of tantalum nitride (TaN) or doped tantalum nitride (TaN). The interconnect structure 300 further includes a second dielectric layer 312, having one or more features 314, such as a via 314V and a trench 314T formed therein, over the first dielectric layer 302 and the conductive layer 306. The second dielectric layer 312 may be formed of the same material as the first dielectric layer 302, such as low k dielectric (SiCOH), silicon dioxide (SiO₂), silicon nitride (Si₃N₄), silicon carbide (SiC), aluminum oxide (Al₂O₃), or aluminum nitride (AlN). In another embodiment, the second dielectric layer 312 may be formed of a different material from the first dielectric layer 302, while maintaining the same low-k properties. A second etch stop layer 316 may be disposed between the second dielectric layer 312 and the first dielectric layer 302.

In one or more examples, as shown in FIG. 3B, the first processing operation includes selectively depositing a passivation layer 318 on an exposed portion 305 of the conductive layer 306. The passivation layer 318 may be formed of a self-assembled monolayer (SAM) of organic molecules. In one example, the SAM may comprise any suitable material such as, but not limited to, include thiols, silanes, phosphonates, alkyne, alkene, imidazole, or combinations thereof. In one example, the passivation layer 318 may be formed using any suitable selective deposition process, such as a soaking process, spin-on process, chemical vapor deposition (CVD), or other similar process. The passivation layer 318 deposition process (i.e., the first processing operation) may be performed in a processing chamber, such as the processing chamber 100 shown in FIG. 1 or a processing chamber separate from processing system 10. In the soaking process, the interconnect structure 300 is exposed to a gas precursor including an unsaturated hydrocarbon, at a temperature of less than about 450° C. and a pressure of less than about 80 Torr for a time duration of greater than about 1 second with a flow rate of the precursor of between 50 sccm and about 600 sccm. In some embodiments, a liquid precursor is used in the soaking process. In the soaking process, organic molecules in the precursor are absorbed only on a metal surface, such as the exposed surface of the conductive layer 306. The passivation layer 318 may act as a block layer that suppresses nucleation or growth of a subsequent material deposition thereon.

At block 207, a single RF frequency plasma is established during a second processing operation. In some embodiments, the process performed during block 207 include the generation of a capacitively coupled plasma (CCP) over the surface of a substrate. In one or more examples, as shown in FIG. 3C, the second processing step includes selectively depositing a barrier layer 330 on the field region of the second dielectric layer 312, the inner sidewalls of the via 314V and the trench 314T, but not the passivation layer 318. The second processing operation may be performed in the processing chamber 100. The selective deposition process can include a plasma enhanced CVD (PECVD) process in which a precursor gas (e.g., metal containing precursor gas (e.g., TiCl₄, WF₆, WCl₅, or WCl₆)) and carrier gas (e.g., He, H₂, Ar, or N₂) are provided to the surface of the substrate disposed in the processing chamber. The barrier layer 330 may be formed of tantalum nitride (TaN) or doped tantalum nitride (TaN), metal doped TaN, titanium nitride (TiN), tungsten nitride (WN), or tungsten nitride carbide (WCN). In one or examples, the second processing operation may include generating a single RF frequency CCP to selectively deposit the barrier layer 320. In one or more examples, the single RF frequency CCP is generated by enabling the first RF generator 118a (or the second RF generator 118b) to generate an RF signal using the system controller 126. For example, the system controller 126 can enable (activate) the first RF generator 118a, causing the first RF generator 118a to provide an RF signal to the upper electrode (i.e., the showerhead plate 123A) and form a single RF frequency CCP. The RF frequency of the CCP is based on the frequency of the signal of the first RF generator 118a. As described above the first RF generator 118a is configured to generate a first RF signal having a frequency greater than 400 kHz, for example greater than 13.56 MHz. For example, the first RF signal may have a frequency greater than 40 MHz, a frequency of 60 MHz or greater, or a frequency between 40 MHz and 120 MHz. The single RF frequency CCP plasma may be generated for a period of time between 1 and 60 seconds, for example 15 seconds in a processing chamber such as processing chamber 100 maintained at a chamber pressure between 0.2 and 100 Torr, for example 3 Torr.

At block 210, the single RF frequency CCP is established to perform a third processing operation on the substrate. The third processing operation may also be performed in the processing chamber 100. In one or more examples, as shown in FIG. 3D, the third processing operation includes removing the passivation layer 318 by exposing the substrate to a single RF frequency CCP that is generated by use of a single frequency RF source. In one example, at block 210, a passivation layer 318 that comprises a SAM is removed. In one process example, similar plasma generation settings, as described above in block 207, are used without the delivery of the precursor gas used to form the barrier layer 330. The single RF frequency CCP plasma may be generated at a frequency of greater than 400 kHz, such as a greater than 40 MHz, a frequency of 60 MHz or greater, or a frequency between 40 MHz and 120 MHz, for a period of time between 1 and 60 seconds while the processing chamber 100 is maintained at a chamber pressure between 0.2 and 100 Torr, for example 3 Torr by use of carrier gas.

At block 215, a dual RF frequency CCP is established to perform a fourth processing operation on the substrate. In one or more examples, as shown in FIG. 3E, the second processing operation includes, generating a dual RF frequency CCP plasma to treat the barrier layer 330, forming a treated barrier layer 335. In one or more embodiments, process gasses used to treat the barrier layer include, but are not limited to, hydrogen, helium, argon, and combinations thereof. In one or more examples, the dual RF CCP plasma is generated by enabling both the first RF generator 118a and the second RF generator 118b using the system controller 126. For example, the system controller 126 enables (activates) the first RF generator 118a and the second RF generator 118b. The first RF generator 118a and the second RF generator 118b each provide an RF signal to the upper electrode (i.e., the chamber lid 123) having a different frequency, forming a dual RF frequency CCP. Stated, differently, the first RF signal is modulated by the second RF signal prior to reaching the upper electrode of the processing chamber, forming the dual RF frequency CCP. The second RF generator 118b is configured to generate a second RF signal also having a frequency greater than 400 KHz. For example, the second RF generator 118b is configured to generate an RF signal with a frequency equal to 13.56 MHz or less, while the first RF generator 118a is configured to generate an RF signal with a frequency greater than 13.56 MHz (e.g., 60 MHz). The dual RF frequency CCP plasma may be generated for a period of time between 1 and 60 seconds, for example 3-5 seconds in a processing chamber such as processing chamber 100 maintained at a chamber pressure between 0.1 and 10 Torr, for example 0.5-1 Torr. Advantageously, generating a dual RF CCP plasma allows for effective modulation of the ion flux and energy to allow for the optimum regime to treat the deposited barrier layer 330 while providing minimal damage to the second dielectric layer 312 (i.e. the low-k material). For example, by controlling the ion flux more effectively the CCP plasma conditions during treatment of the barrier layer 320 can be closer to a conventional inductively coupled plasma (ICP) processing conditions while maintaining the process chamber at a higher pressure than a conventional ICP process. Additionally, the higher pressure direct plasma allows a wider process window for removal of the passivation layer 318, the CCP plasma has no bias from the pedestal and allows for a wider ion angular distribution function (IADF), and helps in structuring the sidewall treatment. Stated differently, the second RF generator 118b is enabled for modulating the first RF signal and the second RF signal. This allows for a weaker, single RF plasma to be generated when removing the passivation layer 318 and depositing the barrier layer so that the dielectrics are not damaged, and then allows generation of a stronger plasma to be generated so that the barrier layer 330 can be fully treated to improve its material properties.

Although the method 200 is described as establishing a single RF frequency CCP to perform the second and third processing operations and then establishing a dual RF frequency CCP to perform a second processing operation, this is for example purposes only. With respect to performing different plasma processing sequences it is understood that the processing system 10 can switch between generating a single RF frequency CCP and a dual RF frequency CCP in any suitable order based on the series of processing steps being performed. Furthermore even though a single RF frequency is described as being generated by enabling the first RF generator 118a, it is understood that a single RF frequency may be generated by enabling the second RF generator 118b.

What is claimed is:

1. A processing method, comprising:
depositing a barrier layer on a field region and sidewalls of a via of an interconnect structure, wherein
depositing the barrier layer comprises establishing a single RF frequency capacitively coupled plasma (CCP) using a first radio frequency (RF) generator coupled to a first electrode of a plasma processing chamber; and
the single RF frequency CCP is formed by delivering a first RF signal from the first radio frequency (RF) generator at a first RF frequency to the first electrode; and
treating the barrier layer by establishing a dual RF frequency CCP in the plasma processing chamber, wherein
the established dual RF frequency CCP is formed by use of the first RF generator and a second RF generator coupled to the first electrode of the plasma processing chamber,
the established dual RF frequency CCP is formed by simultaneously delivering a second RF signal at the first RF frequency to the first electrode and a third RF signal at a second RF frequency to the first electrode, and
the first RF frequency is greater than the second RF frequency.

2. The method of claim 1, wherein the processing method further comprises selectively depositing a passivation layer on an exposed portion of a conductive layer formed within a via of the interconnect structure prior to depositing the barrier layer.

3. The method of claim 2, wherein the passivation layer comprises a self-assembled monolayer (SAM).

4. The method of claim 2, wherein the processing method further comprises removing the passivation layer using the single RF frequency CCP prior to treating the barrier layer, wherein removing the passivation layer comprises establishing a single RF frequency CCP by delivering a fourth RF signal at the first RF frequency to the first electrode.

5. The method of claim 2, wherein the conductive layer comprises copper (Cu), tungsten (W), cobalt (Co), ruthenium (Ru), or molybdenum (Mo).

6. The method of claim 5, wherein the field region and sidewalls comprise a low-k dielectric material.

7. The method of claim 6, wherein the first frequency greater than 13.56 MHz and the second RF frequency that is less than 13.56 MHz.

8. The method of claim 1, wherein the first frequency is greater than 13.56 MHz.

9. The method of claim 1, wherein the second frequency is less than or equal to 13.56 MHz.

10. A plasma processing system comprising:
a first radio frequency (RF) generator coupled an upper electrode of a processing chamber of the plasma processing system, the first RF generator configured to generate a first RF signal having a first frequency;
a second RF generator coupled the upper electrode of the processing chamber of the plasma processing system, the second RF generator configured to generate a second RF signal having a second frequency, the second frequency and the first frequency being different;
a controller; and
a memory for storing instructions, which, when executed by the controller, causes the controller to perform a processing method, the method comprising:
establishing, by use of the first RF generator, a single RF frequency capacitively coupled plasma (CCP), during performing a first processing operation on an interconnect structure; and
establishing, by use of the first RF generator and the second RF generator, a dual RF frequency CCP during performing a second processing operation on the interconnect structure.

11. The plasma processing system of claim 10, wherein the first frequency is greater than the second frequency.

12. The plasma processing system of claim 10, wherein the first frequency is greater than 13.56 MHz.

13. The plasma processing system of claim 10, wherein the second frequency is less than or equal to 13.56 MHz.

14. The plasma processing system of claim 10, wherein the controller is configured to enable the first RF generator and establish a single RF frequency capacitively coupled plasma (CCP) in the processing chamber when removing a passivation layer formed in a via of an interconnect structure.

15. The plasma processing system of claim 14, wherein the passivation layer comprises a self-assembled monolayer (SAM), the first frequency is greater than 13.56 MHz, and the second frequency is less than or equal to 13.56 MHz.

16. The plasma processing system of claim 10, wherein the controller is configured to enable the first RF generator and the second RF generator and establish a dual RF frequency capacitively coupled plasma (CCP) in the processing chamber when treating a barrier layer formed on a field region and on sidewalls of a via of an interconnect structure.

17. The plasma processing system of claim 10, wherein the first RF generator and the second RF generator are coupled to an RF matching network that is coupled to the upper electrode of the processing chamber.

18. The plasma processing system of claim 17, wherein the RF matching network comprises a first RF match coupled to the first RF generator and a second RF match coupled to the second RF generator.

19. The plasma processing system of claim 10, wherein the processing chamber further comprises a substrate support assembly comprising biasing electrode coupled to a clamping network and a grounded substrate support base.

20. The plasma processing system of claim 19, wherein the clamping network comprises bias compensation circuit elements coupled to a DC power supply.
